(19) United States
(12) Patent Application Publication
(10) Pub. No.: US 2023/0002932 A1
(43) Pub. Date: Jan. 5, 2023

(54) METHOD FOR FORMING FREESTANDING MICROSTRUCTURES ON A DIAMOND CRYSTAL AND DIAMOND CRYSTAL

(71) Applicant: Q.ant GmbH, Stuttgart (DE)

(72) Inventors: Robert Roelver, Calw (DE); Michael Foertsch, Ansbach (DE); Stefan Hengesbach, Stuttgart (DE)

(21) Appl. No.: 17/855,885

(22) Filed: Jul. 1, 2022

(30) Foreign Application Priority Data
Jul. 2, 2021 (DE) 10 2021 206 956.8

(51) Int. Cl. C30B 33/04; G02B 6/122; G02B 6/13; C30B 29/04; B23K 26/402

(52) U.S. Cl. CPC C30B 33/04; G02B 6/122; G02B 6/13; C30B 29/04; B23K 26/402

(57) ABSTRACT

A method for forming at least one freestanding microstructure on a diamond crystal includes the step of removing material from the diamond crystal so as to form a structured surface, wherein the removing of the material includes creating at least two trenches, each trench having a bottom and two side walls and wherein adjacent side walls of the at least two trenches form side walls of the structured surface. The method also includes the steps of depositing at least one masking layer on the structured surface, removing at least a portion of the at least one masking layer from the bottom of each of the at least two trenches, removing additional material from the diamond crystal at least along the side walls so as to deepen the trenches, and undercutting the diamond crystal so as to form the freestanding microstructure.

### CROSS REFERENCE TO RELATED APPLICATIONS

This application claims benefit to German Patent Application No. DE 10 2021 206 956.8, filed on Jul. 2, 2021, which is hereby incorporated by reference herein.

### FIELD

The present invention relates to the formation of microstructures, which are in particular optically usable, for example, of optically usable waveguide structures, on a diamond crystal (a diamond monocrystal) and a diamond crystal having at least one such microstructure or waveguide structure.

### BACKGROUND

There are different approaches for the formation of microstructures, for example, of waveguide structures, in optical crystals. One approach is to inscribe the waveguides by index of refraction modification into the optical crystal, as described, for example, in the article “High-repetition-rate femtosecond-laser micromachining of low-loss optical-lattice-like-waveguides in lithium niobate”, T. Piromjitpong et al., Proc. of SPIE Vol. 10684 (2018). A further approach is to produce the microstructures by laser ablation.

Both approaches are described in the article “Optical waveguides in crystalline dielectric materials produced by femtosecond-laser micromachining”, Feng Chen et. al., Laser Photonics Rev. 8, No. 2, 2014. It is specified there, inter alia, that ridge waveguides can be produced by laser ablation in that channels are introduced into the substrate, between the side walls of which the ridge waveguide is formed. It is also described therein that a disadvantage of the ridge waveguides produced in this way is that rough side walls are formed during the laser ablation using femtosecond laser pulses, which reduce the quality of the ridge waveguide and increase its losses.

A method for producing a substrate is described in EP 0 803 747 A2, which is provided with an optical waveguide in the form of a ridge waveguide. The ridge waveguide is produced by laser ablation, for example, using an excimer laser at wavelengths between 150 nm and 300 nm and pulse durations in the range of nanoseconds. For this purpose, the laser beam can be aligned on a surface of the substrate and moved or scanned over the substrate. The optical axis of the laser beam is aligned vertically in relation to the surface of the substrate for this purpose. The ridge waveguide is to have the most rectangular possible cross-sectional profile to avoid light losses.

The production of microstructures in a diamond crystal is made more difficult in comparison to crystals made of other materials in that the carbon atoms have an extremely high bonding energy and therefore the laser ablation threshold is very high upon the use of pulsed (UV) lasers at 2 J/cm². Etching processes are therefore typically used for the microstructuring of diamond, for example, reactive ion etching, cf. the article “Inverse Designed Diamond Photonics”, C. Dori et al., nature communications (2019) 10:3309, the article “Development of all-diamond scanning probes based on Faraday cage angled etching techniques” by C. Giese et al., MRS Advances, Vol. 5, pp. 1899-1907 (2020), in which an RF bias cage is used in the reactive ion etching, or the article “Anisotropic diamond etching through thermochemical reaction between Ni and diamond in high-temperature water vapour”, M. Nagai et al., Scientific Reports (2018) 8:6687, in which an etching process with the aid of a thermochemical reaction between Ni and diamond in high-temperature water vapour is described.

Due to the limited interaction depths of the fs lasers typically used for laser ablation, previous experiments in microstructuring of diamond crystals by laser ablation have been limited to the production of laser-induced periodic surface structures having structure sizes of typically less than 200 nm, cf., for example, the article “Photonic structures in diamond based on femtosecond UV laser induced periodic surface structuring (LIPSS)”, E. Granados et al., Optics Express, Vol. 25, No. 13, p. 15330.

In the article “Nonlinear photooxidation of diamond surface exposed to femtosecond laser pulses”, V. V. Kononenko et al., Laser Phys. Lett. 12 (2014) 096101, it is described that upon the irradiation of diamond using fs laser pulses, a photo-induced oxidation of the carbon of the diamond crystal occurs, during which volatile etching products such as CO or CO₂ are formed. In the article “Nonlinear photooxidation of diamond surface exposed to femtosecond laser pulses”, V. I. Konov, Laser Physics Letters 12 (2015), 096101, it is described, inter alia, that the desorption rate of carbon species during the photooxidation is proportional to the square root of the induced plasma density.

The optically usable microstructures which are inscribed in a diamond crystal can be, for example, waveguide structures or geometries for collecting light. In particular if the diamond crystal is doped with colour centres, for example, with NV (“nitrogen vacancy”) centres, it can be used for implementing quantum sensors, for quantum cryptography, up to implementing quantum computers. In all of these applications, the fluorescence of the colour centres is used as an information carrier, which has to be read out efficiently. In diamond-based quantum sensors, light-guiding microstructures in the diamond crystal can contribute to increasing the signal-to-noise ratio upon readout and thus improving the sensitivity of the quantum sensors. For example, the microstructures in diamond crystals which are doped with colour centres can be used, on the one hand, to enable an optimum optical excitation density of excitation light at an excitation wavelength (upon the use of NV centres, for example, between 510 nm-550 nm) and, on the other hand, an optimum collection of the florescent light generated by the excitation light (for example, at fluorescence wavelengths between 620 nm-680 nm), for example, to supply the florescent light to a detector. Further applications of the microstructuring of diamond crystals are precise laser processing and structuring of diamond components such as laser windows, diamond-based tweeters in loudspeakers, or diamond components for heat dissipation in electronic circuits and switchgear.

To form microstructures of these types and others, directly writing laser ablation methods suggest themselves. The precise formation of microstructures, i.e., of structures having structure widths in the micrometre range, by laser ablation in a diamond crystal has not been possible up to this point due to the problems described further above, however. In particular, no method for three-dimensional structuring of a diamond crystal is known, in which freestanding microstructures or waveguide structures are formed in the diamond crystal.

### SUMMARY

In an embodiment, the present disclosure provides a method for forming at least one freestanding microstructure on a diamond crystal includes the step of removing material from the diamond crystal so as to form a structured surface, wherein the removing of the material includes creating at least two trenches, each trench having a bottom and two side walls and wherein adjacent side walls of the at least two trenches form side walls of the structured surface. The method also includes the steps of depositing at least one masking layer on the structured surface, removing at least a portion of the at least one masking layer from the bottom of each of the at least two trenches, removing additional material from the diamond crystal at least along the side walls so as to deepen the trenches, and undercutting the diamond crystal so as to form the freestanding microstructure.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic illustration of a device for forming waveguide structures on a heated diamond crystal by removing material to form multiple trenches extending in parallel by means of a pulsed laser beam;

FIG. 2 shows two of the trenches from FIG. 1 in cross section during their production by laser ablation;

FIG. 3 shows a schematic illustration of a device similar to FIG. 1, in which the diamond crystal covered using a masking layer is arranged in a gas-tight process chamber to expose the waveguide structures by isotropic oxidation of the diamond crystal;

FIGS. 4a, 4b, and 4c show illustrations of a thermal oxidation for smoothing the waveguide structures, which were formed during the material removal described in conjunction with FIG. 1;

FIGS. 5a, 5b, 5c, 5d, 5e, 5f, and 5g show illustrations of multiple method steps for forming the freestanding waveguide structures of FIG. 3; and

FIGS. 6a, 6b, 6c, and 6d show illustrations of multiple method steps for forming freestanding waveguide structures in a buried layer of a diamond crystal doped with NV centres.

### DETAILED DESCRIPTION

The invention is based on the object of providing a method for forming freestanding microstructures, in particular having freestanding waveguide structures, in a diamond crystal and a diamond crystal having at least one such freestanding microstructure, in particular having such a freestanding waveguide structure.

This object is achieved by a method for forming at least one freestanding microstructure, in particular a freestanding waveguide structure, on a diamond crystal, which comprises the following steps: structuring a surface of the diamond crystal by removing material to form at least two trenches, the adjacent side walls of which form the side walls of a microstructure, in particular a waveguide structure, depositing at least one masking layer on the structured surface, at least partially removing the masking layer from the bottom of the trenches, deepening the trenches by additionally removing material of the diamond crystal at least along the side walls, and forming the freestanding microstructure, in particular the freestanding waveguide structure, by undercutting the microstructure, in particular the waveguide structure.

In the method according to the invention, initially the surface of the diamond crystal is structured to form the side walls and the upper side of the later freestanding microstructure, in particular the freestanding waveguide structure. At least one masking layer is subsequently applied in a planar manner to the structured surface. The masking layer is selectively removed in a subsequent step only in the region of the bottom of the trenches in order to be able to deepen the trenches at least along the side walls in a following step.

The at least partial removal of the masking layer from the bottom of the trenches can be carried out by removing material by means of laser ablation. Alternatively to the selective removal of the masking layer in the region of the bottoms of the trenches by laser ablation, a so-called lift-off process can also be used, in which a photoresist is lithographically structured so that it only remains in the region of the bottoms of the trenches. After the masking layer is deposited over the entire surface, the remaining photoresist is removed, for example, by a solvent attack, due to which the masking layer present on the remaining photoresist is also dissolved or removed simultaneously.

Due to the deepening, a section is formed on a respective side wall which is not covered by the masking layer. This section of the side wall of the trench is accessible to an etching attack and enables the microstructure, in particular the waveguide structure, to be undercut. The etching attack therefore takes place underneath the freestanding microstructure or waveguide structure to be produced. The undercutting typically takes place with the aid of an isotropic etching process in the form of a dry etching process.

The removal of the material, the at least partial removal of the masking layer, and the additional removal of the material are carried out with the aid of anisotropic methods, typically by laser ablation (see above), in contrast to etching. If the masking layer used should be optically absorbing in the wavelength range used, the masking layer is to be completely removed from the structured surface after the exposure of the microstructures. The removal of the masking layer can also be carried out by laser ablation or possibly with the aid of a wet etching or a dry etching process.

The inventors have recognized that conventional methods for three-dimensional structuring of crystals, in which freestanding microstructures are formed by undercutting, cannot be applied in the case of a diamond crystal: A three-dimensional structuring of the surface of a diamond crystal by 3D lithography and a subsequent reactive ionic etching method is not possible due to the low selectivity (approximately 30:1) of known hard masks, which are used during the etching of diamond by means of reactive ion etching. Using such a method, only three-dimensional depth structures in the order of magnitude of a few 100 nm can be implemented, which are not suitable as optically usable microstructures or waveguide structures. In contrast thereto, in the method described here, freestanding microstructures can be generated which have a height in the order of magnitude of micrometres.

In one variant, the undercutting of the microstructure, in particular the waveguide structure, is carried out by thermal oxidation of the diamond crystal at a temperature between 600° C. and 1100° C., for example, between 650° C. and 1000° C., preferably in an oxygen-containing atmosphere, in particular in an oxygen plasma. The thermal oxidation of the diamond crystal represents an isotropic etching process in which only the regions of the surface of the diamond crystal not covered by the masking layer are attacked. The process duration of the thermal oxidation conforms to the etching speed which prevails in the case of the respectively set process parameters (temperature, pressure, oxygen content in the environment, etc.) and can be from a few seconds to several minutes. The oxygen-containing atmosphere in the environment of the diamond crystal can have molecular oxygen admixed, however, it is also possible that reactive gases which contain oxygen, for example, NO or N₂O, are admixed to the oxygen-containing atmosphere. It is possible that an oxygen plasma is used for the undercutting, for example, if the step of undercutting is carried out in a conventional CVD reactor. The reactivity of the oxygen is increased by the oxygen plasma and the process temperature required for the thermal oxidation can be reduced.

In a further variant, to smooth the structured surface, a thermal oxidation of the structured surface is carried out (before the deposition of the masking layer) at a temperature between 600° C. and 1100° C., for example, between 650° C. and 1000° C. or between 800° C. and 1000° C., preferably in an oxygen-containing atmosphere. In this variant, smoothing of the structured surface and thus also of the microstructures or the waveguide structures is carried out by generally brief thermal oxidation of the structured surface at durations which are typically between a few seconds and one minute. The process parameters, in particular the temperature, the pressure, and the duration of the thermal oxidation, are set deliberately to minimize roughness, without a material removal occurring here, as is the case during the undercutting described further above. The basis of the smoothing is the fact that a rough surface offers more attack possibilities for an oxidative reaction than a smooth surface and therefore a rough surface oxidizes faster than a smooth surface. It is obvious that such a smoothing of microstructures or waveguide structures can also advantageously be applied if no freestanding microstructures or waveguide structures are formed, i.e., if the further above-described steps such as the deposition of the at least one masking layer, etc. are not carried out.

In one variant, the deposition of the at least one masking layer is carried out by chemical vapour deposition (CVD) or by atomic layer deposition (ALD). The masking layer is used to protect the structured surface before the following isotropic etching attack. The deposition of the masking layer by a CVD or an ALD process enables a conformal deposition in which both the upper side of the microstructures and also their side walls are covered as homogeneously as possible, in order to create isotropic undercutting only at the desired locations. Temperature-stable nitrides or oxides, for example, SiO₂, Al₂O₃, SiN, or other amorphous, temperature-stable oxides or nitrides such as TiO or TiO₂, ZrO, TiN, AlN, . . . have proven to be advantageous as materials for the masking layer. Typical layer thicknesses of the masking layer are in the order of magnitude between approximately 10 nm and approximately 1000 nm, ideally between 200 nm and 300 nm.

In a further variant, the removal of the material, the at least partial removal of the masking layer, and/or the additional removal of the material are carried out by laser ablation by means of a preferably pulsed laser beam. A pulsed laser beam in the form of an ultrashort pulse laser beam has proven to be advantageous for the laser ablation of diamond material (see below). An ultrashort pulse laser beam can also be used for the at least partial removal of the masking layer, however, it is also possible that the removal of the masking layer is carried out in c/w operation or using a laser beam having significantly longer pulse durations. It is possible that a laser beam is used for the partial removal of the masking layer, the wavelength of which does not correspond to the wavelength of the laser beam used for the removal or the additional removal of the material of the diamond crystal.

In one refinement of this variant, a temperature of the diamond crystal during the removal of the material and/or during the additional removal of the material is greater than 600° C., preferably greater than 700° C., in particular greater than 800° C., and less than 1000° C.

The inventors have recognized that diamond is very inert up to a specific threshold temperature and does not display any reactive behaviour even in the presence of oxygen. Upon exceeding the threshold temperature, diamond reacts very quickly with oxygen and combusts at the same time (thermal oxidation). The ablation threshold of the diamond material decreases with increasing temperature and accordingly the etching rate of the diamond material increases—with otherwise identical process conditions. If the threshold temperature is exceeded, the diamond material generally burns off in an uncontrolled manner, so that the temperature of the diamond material is to be kept below the threshold temperature.

It has been shown that at temperatures of the diamond material of greater than 600° C., 700° C., or 800° C., the ablation threshold can be decreased significantly and the removal rate per laser pulse can thus be significantly increased. It is therefore advantageous to keep the temperature of the diamond material during the formation of the microstructure(s) just below the threshold temperature of the diamond material for thermal oxidation, which is typically in the order of magnitude of approximately 1000° C.

The material removal during the structuring of the diamond crystal therefore preferably takes place by way of a combination of a laser introduction and a temperature introduction. The pulse energies of the pulsed laser beam which is used for the laser ablation can be reduced by the additional temperature action on the diamond crystal. In this way, the structural integrity and the surface quality during the formation of the microstructures can be improved. The temperature introduction moreover has the advantage that the debris which is created during the laser ablation is reduced, since amorphized carbon components in the debris combust immediately at temperatures of greater than 600° C. due to the lower oxidation temperature in comparison to diamond.

A temperature-control unit can be used to heat up the diamond crystal to the temperatures indicated further above. The temperature-control unit is generally a heating unit, but it can possibly be a unit which is designed to both heat and also cool the diamond material. The temperature-control unit can be, for example, a resistance heater or a susceptor heated via IR radiation or in another way, for example, made of silicon. The temperature-control unit is typically used to heat up not only the surface of the diamond crystal, which is irradiated using the pulsed laser beam, but the entire diamond crystal as homogeneously as possible. The temperature-control unit keeps the diamond crystal, during the formation of the microstructure(s), at a temperature which is in the above-specified value range. It is possible, but not absolutely necessary, to set the temperature of the diamond crystal to a specific temperature value with the aid of the temperature-control unit and to keep it at this temperature during the formation of the microstructure(s). It is possible to monitor the temperature at the surface of the diamond crystal with the aid of a temperature sensor or the like and possibly to regulate it to a predefined temperature setpoint value or a predefined setpoint temperature curve.

In one refinement, the removal of the material comprises: radiating the pulsed laser beam on the surface of the diamond crystal, moving the pulsed laser beam and the diamond crystal in relation to one another along a feed direction along at least one ablation path, wherein preferably the laser beam and the diamond crystal are moved in relation to one another multiple times along laterally offset ablation paths to form the trenches.

To form the microstructure or a respective trench, in general multiple ablation paths are offset in parallel to one another systematically. The ablation paths either extend linearly or form curved structures in the XY plane on the surface of the crystal. In this way, for example, meandering structures or tapers can be created. Typically, multiple ablation paths are superimposed laterally and possibly vertically, i.e., in the thickness direction of the diamond crystal. In this way, trenches having a predefined width and depth can be created in the diamond crystal. In dependence on the desired geometry, the laser parameters can also be adapted in dependence on the respective ablation path. For details of the formation of microstructures in the form of (ridge) waveguides between two adjacent trenches, reference is made to DE 10 2019 214 684 A1, which is made part of the content of this application in its entirety by reference.

The two trenches, between which the microstructure is formed, have a predefined distance from one another which defines the width of the microstructure. It is not necessary for this distance to be constant, rather it is possible that the distance and thus the width of the microstructure or the (ridge) waveguide varies in the longitudinal direction of the trenches. The same applies to the depth of the trenches, which define the height of the side walls of the microstructure and thus the height of the microstructure.

During the radiation of the laser beam on the surface of the diamond crystal, a beam axis of the laser beam can be aligned perpendicularly to the generally planar surface of the diamond crystal. In this case, a translation movement of a bearing unit typically takes place, for example, in the form of a translation platform, on which the generally plate-shaped crystal is mounted during the formation of the microstructures, in a horizontal plane (parallel to the surface of the diamond crystal). The laser processing head, from which the pulsed laser beam exits and is aligned on the surface of the diamond crystal, can be arranged fixed in place for this purpose, however, it is also possible that the laser processing head is moved over the surface of the diamond crystal. The laser beam exiting from the laser processing head is typically focused in this case on the surface of the diamond crystal.

During the movement of the laser beam and the diamond crystal in relation to one another, alternatively a beam axis of the laser beam can be tilted at an angle in relation to a normal direction of the surface of the diamond crystal, wherein the angle is preferably in a plane perpendicular to the feed direction. In this case, the laser beam is not incident perpendicularly, but rather at an angle not equal to 0° on the surface of the diamond crystal. The feed direction of the ablation path along which the material is removed generally extends in parallel to the processing plane or to the surface of the diamond crystal. The angle at which the laser beam is tilted in relation to the normal direction of the surface is typically in a plane which extends perpendicularly to the feed direction (which possibly varies depending on location), but this is not absolutely required.

As described in DE 10 2019 214 684 A1, which is made part of the content of this application in its entirety by reference, due to the alignment at the angle, it is possible to achieve that one of the two side walls or side edges of the ablation path extends steeper and the other side wall of the ablation path, which is created in the diamond crystal, extends flatter than would be the case with perpendicular incidence of the laser beam on the surface.

The above-described angle is typically between 2° and 60°, preferably between 10° and 45°, in particular between 15° and 30°. It has proven to be advantageous to select the angle at which the laser beam is aligned in relation to the normal direction in the specified interval in order to achieve that one of the two side walls of the ablation path is aligned as steeply as possible, i.e., as parallel as possible to the normal direction of the surface. For the case in which the side wall of the ablation path or the trench in the diamond crystal forms the side wall of a microstructure, for example, a waveguide, the steepest possible alignment is advantageous, since in this way light losses due to the escape of light guided in the waveguide through the side wall can be kept low. Rotationally symmetrical eigenmodes can be guided in the waveguide by steep side walls and a settable aspect ratio of height to width.

For the case in which linear ablation paths are to be created, the feed direction during the relative movement of the laser beam and the diamond crystal is constant. The feed direction can vary depending on location if curved ablation paths or microstructures are to be created. In both cases, it is to be ensured that the angle at which the laser beam is tilted in relation to the normal direction of the surface of the diamond crystal can be set independently of the selected feed direction—which possibly varies depending on location. In a conventional laser scanner, which is fixed in place, for processing a workpiece arranged fixed in place, this is typically not the case, since the laser beam is aligned at a predetermined scanning angle at a respective position on the surface of the workpiece. There are various possibilities for tilting the beam axis of the laser beam at an angle in relation to the normal direction of the surface of the diamond crystal independently of the feed direction. For details, reference is made to DE 10 2019 214 684 A1.

If a laser beam having a round beam profile is radiated at an angle to the surface of the diamond crystal, it is thus incident with an elliptical, non-rotationally symmetrical beam profile (spot) on the surface. To nonetheless generate a round beam profile on the surface, a laser beam having an elliptical beam profile can be radiated onto the surface. Such an elliptical beam profile can be generated by means of a beamforming optical unit, for example, with the aid of a cylinder lens or a lens telescope or the like. In particular, such a beamforming optical unit can be designed to change the aspect ratio of the elliptical beam profile. For details of the radiation of a laser beam having an elliptical beam profile onto a crystal, reference is also made to DE 10 2019 214 684 A1, cited further above.

It can possibly be advantageous if the beam profile of the laser beam deliberately deviates from a round or rotationally symmetrical geometry, for example, to generate a line focus on the surface of the diamond crystal, as described, for example, in WO 2018/019374 A1, which is made part of the content of this application in its entirety by reference. Such a line focus can be generated, for example, by using asymmetrical modes. The roughness of the produced microstructures can also be improved upon the use of a line focus.

In a further refinement, the pulsed laser beam is radiated at a wavelength of less than 450 nm onto the surface of the diamond crystal. It has been shown that the use of a wavelength of the pulsed laser beam in the UV wavelength range significantly improves the quality of the (optically usable) microstructures produced during the laser ablation in the diamond material. A laser beam having a greater wavelength can possibly be used for the removal of the marking layer.

The pulsed laser beam is typically radiated at pulse durations of less than 20 ps, preferably less than 850 fs, particularly preferably less than 500 fs, in particular less than 300 fs onto the surface of the diamond crystal in order to remove the material of the diamond crystal. It has been shown that the use of pulse durations in the fs range significantly improves the quality of the produced microstructures. As was described further above, it is not absolutely necessary for the removal of the masking layer that the laser beam has the pulse durations described further above.

The pulsed laser beam can be generated, for example, by a solid-state laser or by an excimer laser. Solid-state lasers enable the generation of laser pulses having low pulse durations in the fs range. Solid-state lasers can generate wavelengths in the UV wavelength range, for example, at 343 nm, by frequency doubling or frequency multiplying. Alternatively, it is possible that the pulsed laser beam is generated by an excimer laser.

Repetition rates between approximately 600 kHz and 1000 kHz are typically used as laser parameters for the ablation described further above. It is possible that the repetition rate varies, i.e., that short, high repetition rates followed by long pulse pauses are used for the ablation (burst operation). Typical feed speeds are between approximately 500 and 1500 mm/s and are therefore higher than in conventional production methods. The average laser power is in the order of magnitude between approximately 1 and 2.5 Watts, the energy introduction per laser pulse is in the order of magnitude between approximately 1.5 and 5 μJ. In principle, the removal rate and the structure depth may be set deliberately by a targeted combination of pulse energy, pulse duration, and pulse number as well as feed speed and angle of the laser beam in relation to the surface.

In a further variant, the diamond crystal is preferably arranged jointly with the temperature-control unit in a gas-tight process chamber during the undercutting, during the removal of material, during the additional removal of material, and/or during the smoothing of the structured surface. The gas-tight process chamber can be subjected to a defined gas atmosphere, which simplifies the process control. In particular for the case in which the temperature-control unit heats the diamond crystal by the emission of contact heat (conduction), it is advantageous or required for the temperature-control unit to be arranged jointly with the diamond crystal in the process chamber. For the radiation of the pulsed laser beam into the process chamber during the laser ablation, the process chamber typically has a window which is transparent to the wavelength of the pulsed laser beam, for example, a window made of quartz glass. The process chamber can be connected to a pump which suctions gas out of the interior of the process chamber. The pump can in particular be a vacuum pump. Typically, all relevant process parameters such as the temperature of the diamond crystal or the environment of the diamond crystal, the pressure, and the oxygen content can be set with the aid of the process chamber, as described further below.

In an interior of the process chamber, the oxygen-containing atmosphere described further above can be generated, which can be used during the undercutting, during the smoothing of the structured surface, during the removal, and/or during the additional removal of material of the diamond crystal in order to strengthen the thermal oxidation or the action of the pulsed laser beam on the diamond material. The use of oxygen as a reactive gas component in the process chamber has proven to be advantageous for carrying out the method. As was described further above, the use of other reactive gases is also possible, for example, NO or N₂O. The oxygen content or the partial pressure of the oxygen in the process chamber can preferably be set with the aid of a suitable inlet, for example, with the aid of a controllable valve.

At least one inert gas, preferably nitrogen, can also be contained in the process chamber. The inert gas makes it possible to have the laser ablation process run in a controlled manner, in particular if a reactive gas component is contained in the process chamber. Preferably, the content or the partial pressure of the inert gas in the process chamber can be set, for example, in that the inert gas is supplied to the process chamber with the aid of a controllable inlet, for example, using a switchable or controllable valve. It is advantageous if a practically arbitrary mixing ratio of the reactive gas and the inert gas can be set in the process chamber. To achieve this, the inert gas and the reactive gas can preferably be supplied to the process chamber via two separately settable or controllable valves.

In particular for the step of undercutting and for the step of smoothing, it is advantageous if a gas pressure in the process chamber is set, preferably regulated, to improve the process control. As was described further above, the process chamber is typically connected to a pump, which suctions gas out of the interior of the process chamber. The total pressure or the gas pressure in the process chamber can be measured with the aid of a pressure meter and the pump or a valve can be activated suitably with the aid of a control or regulating device in order to keep the total pressure in the process chamber to a predefined setpoint value. The reduction of the gas pressure in the process chamber is used to reduce the reaction speed during the crystal processing and offers a further degree of freedom in the process control. The gas pressure in the process chamber during pressure-reduced processing is typically in a range between 10 mbar and 100 mbar. For the case in which the pump is connected via a switchable valve to the interior of the process chamber, the pump can be separated from the interior of the process chamber by closing the valve, as soon as the desired total pressure is reached in the process chamber.

In a further refinement, the diamond crystal is doped in the region of the freestanding microstructure, in particular the freestanding waveguide structure, with colour centres, preferably with NV centres. In the three-dimensional structuring of the diamond crystal described here, freestanding microstructures can be deliberately generated, in the volume of which the diamond crystal is doped with colour centres. It is possible to limit the doping with the colour centres to the freestanding microstructures, in particular the freestanding waveguide structures, i.e., that the diamond crystal is not doped with colour centres outside the freestanding waveguide structures. Freestanding waveguide structures which are doped with colour centres, in particular with NV centres, can be used, for example, as active sensor or measuring regions to enable a localized measurement, for example, of magnetic fields or of tensions. The freestanding waveguide structure enables the excitation density of excitation light which is supplied to the freestanding waveguide structure to be optimized by a suitable selection of the geometry. The extent of the measuring regions can be limited in the vertical direction by the exposure. Moreover, the geometry of the freestanding waveguide structure can be adapted for the optimization of the excitation density, for example, the cross section of the freestanding waveguide structure can decrease in the propagation direction of the excitation light, which can be achieved by a tapering, truncated-cone-shaped or wedge-shaped geometry.

In one refinement, the method comprises: forming at least one further microstructure, preferably at least one further waveguide structure, in the diamond crystal, which is used in particular to supply excitation light to the freestanding waveguide structure and/or to discharge fluorescent light from the freestanding waveguide structure, wherein the diamond crystal is not doped in the region of the at least one further microstructure, preferably the at least one further waveguide structure, with colour centres, preferably is not doped with NV centres. As described further above, the freestanding waveguide structure can be used as an active region, for example, as a measuring region, in which excitation light is converted into fluorescent light. The further waveguide structures can be used as passive regions for improving the light guiding during the supply of excitation light to the freestanding waveguide structure and for discharging fluorescent light from the freestanding waveguide structure or for collecting the light emissions of the colour centres.

To ensure a mechanical stability of the exposed microstructures or waveguide structures or to ensure a mechanically stable connection of the microstructures or the waveguide structure to the remaining diamond substrate and to adapt the freestanding microstructures or waveguide structures to the photonic layout to be implemented, support structures can be used. The support structures are to have as little contact surface as possible with the actual waveguide structures, but are to be structured sufficiently large that they are not completely undercut during the exposure of the microstructures or the waveguides. The further microstructures or the further waveguide structures are typically inscribed in the diamond crystal before the masking layer is deposited on the structured surface.

In one refinement, the diamond crystal comprises a first layer, which is doped with the colour centres, preferably with the NV centres, and the diamond crystal comprises a second layer, which adjoins the first layer and which is not doped with the colour centres, preferably not with the NV centres, wherein the freestanding microstructures, preferably the freestanding waveguide structures, are formed in the first layer, and wherein the further microstructures, preferably the further waveguide structures, are formed in the second layer, which preferably adjoins the surface of the diamond crystal. In this refinement, the light, for example, in the form of excitation light, can initially be guided starting from a coupling position with the aid of the further waveguide structures into the second, undoped layer. The light can then be transferred at a transition between the further waveguide structure and the freestanding waveguide structure into the first layer, which is doped using the colour centres and can be used, for example, for sensory measurement. This has the advantage that the light can be guided undisturbed up to a respective measuring region inside the diamond material and only interacts with the colour centres at the location at which a measurement is to take place.

To produce such a structured diamond crystal, typically a diamond crystal is used as the starting material in which the first layer forms a buried layer, which is doped with the colour centres, while the second layer adjoins the surface of the diamond crystal from which the material of the diamond crystal is removed. The doped buried layer can be created in the diamond crystal in a manner known to a person skilled in the art. In the second, surface-proximal layer, the further waveguide structures are formed, while in the first, buried layer, the freestanding microstructures or waveguide structures are formed. The formation of the freestanding waveguide structures and the further waveguide structures can take place in this case in that trenches are formed, the depth of which varies, so that the trenches extend at least along a section, along which the freestanding microstructures are formed, in the first, buried layer to form the side walls of the freestanding microstructures, while the trenches do not extend in the first layer along a section along which the further microstructures or waveguide structures are formed—with the exception of a transition region. However, it is also possible in principle that the role of the first layer and the second layer is exchanged, i.e., that the first layer which has the colour centres adjoins the surface of the diamond crystal. The diamond crystal can be produced, for example, via chemical vapour deposition (CVD). To achieve the doping in the first layer, but not in the second layer, for example, doping gas can deliberately be switched on and off during the CVD growth process.

In one refinement, the structuring of the surface comprises the removal of the material of the second layer above the microstructure to be formed, in particular the waveguide structure to be formed, to expose the upper side of the microstructure to be formed, in particular the waveguide structure to be formed. For the case that the freestanding microstructure or waveguide structure is formed in the second, buried layer, it is necessary for the material of the first layer to be removed above the microstructure or waveguide structure to be formed in order to create the upper side of the freestanding microstructure or waveguide structure. In a region adjoining the upper side of the microstructure, a material removal in the second layer typically also takes place in order to form a transition region between the freestanding microstructure and those further microstructures which adjoin the freestanding microstructure. The exposure of the microstructure or the waveguide structure takes place as described further above, i.e., by the removal of material to create the trenches, the deposition of a masking layer, the partial removal of the masking layer, and the subsequent (isotropic) undercutting.

A further aspect of the invention relates to a diamond crystal, comprising: at least one freestanding microstructure, in particular at least one freestanding waveguide structure, which is produced according to the method described further above. The diamond crystal can have the further microstructures or waveguide structures described further above in addition to the microstructure or waveguide structure. In particular, the freestanding microstructures or waveguide structures can be doped with colour centres, in particular with NV centres, while this is not the case in the further microstructures or waveguide structures.

Further advantages of the invention result from the description and the drawing. The above-mentioned features and the features set forth further below can also be used as such or together in arbitrary combinations. The embodiments shown and described are not to be understood as an exhaustive list, but rather have exemplary character for the description of the invention.

In the following description of the drawings, identical reference signs are used for identical or functionally identical components.

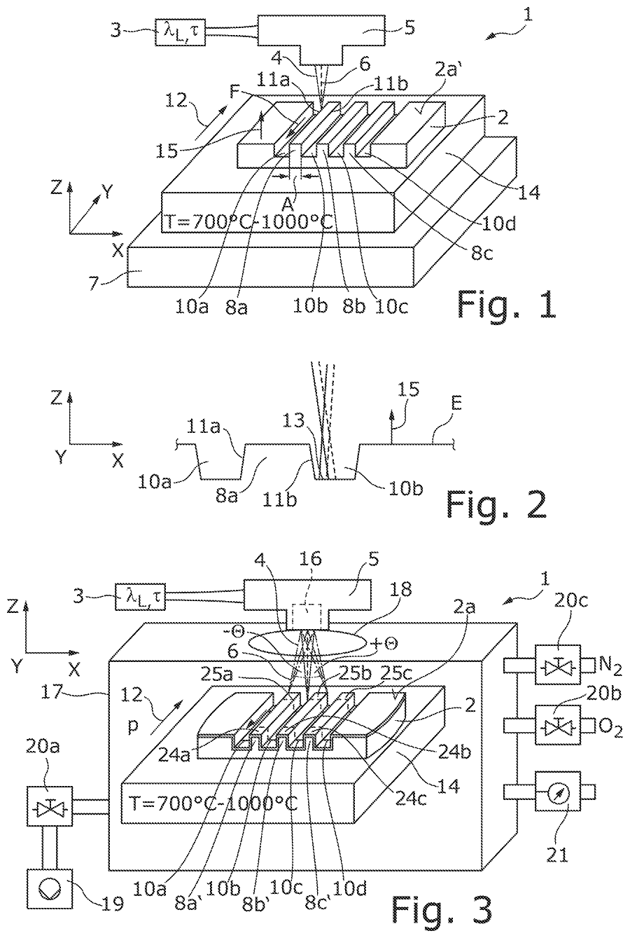

FIG. 1 shows an exemplary structure of a device 1 for forming microstructures or waveguide structures on a substrate in the form of a diamond crystal 2 (diamond monocrystal). The device 1 comprises a laser source 3 for generating a laser beam 4, which is supplied via a beam guide indicated in FIG. 1 to a laser processing head 5. The laser processing head 5 aligns the laser beam 4 on the diamond crystal 2, precisely on a surface 2a′ of the diamond crystal 2, which forms the upper side of the diamond crystal 2 in the example shown. The surface shown in FIG. 1 is a structured surface 2a′ of the diamond crystal 2 after the formation of the microstructures, which was formed by material removal from a planar surface of the diamond crystal 2.

The laser source 3 is, in the example shown in FIG. 1, a solid-state laser, which is designed to generate the laser beam 4 at a wavelength λ_{L} of 343 nm. The solid-state medium of the laser source 3 can be, for example, Yb:YAG. The laser source 3 can also be designed to generate a laser beam 4 at another wavelength in the wavelength range of less than 450 nm.

The laser source 3 is designed to generate a pulsed laser beam 4 having pulse durations in the ps or fs range. For the method described hereinafter, pulse durations τ of less than 20 ps, for example of less than 850 fs, in particular of less than 500 fs, possibly of less than 300 fs have proven to be advantageous.

The laser source 3 which is designed to generate a pulsed laser beam 4 having such pulse durations can be, for example, a plate, slab, or fibre laser. Alternatively, an excimer laser can possibly be used, although this is generally not suitable for generating pulse durations in the fs range.

The pulsed laser beam 4 is radiated onto the surface 2a of the diamond crystal 2 facing towards the laser processing head 5. As can be seen in FIG. 1, a beam axis 6 of the laser beam 4 is aligned perpendicularly to the surface 2a of the diamond crystal 2, which forms the processing plane in the example shown. The diamond crystal 2 is mounted on a translation platform 7, which can be displaced with the aid of actuators (not shown in the figures) in the X direction and independently thereof in the Y direction and in the Z direction of an XYZ coordinate system. The translation platform 7 can also be rotated around an axis of rotation aligned in the Z direction.

As can be seen in FIG. 1, during the material-removing processing of the diamond crystal 2 by means of the pulsed laser beam 4, microstructures in the form of three waveguide structures, which are aligned in parallel and extend in the Y direction, in the form of ridge waveguides 8a-c are formed, which have an essentially rectangular cross section. For this purpose, four trenches 10a-d, which are aligned in parallel and also extend in the Y direction, are introduced into the diamond crystal 2 by means of the pulsed laser beam 4. The three ridge waveguides 8a-c are each arranged between two adjacent trenches 10a-d.

As shown by way of example in FIG. 1 for the first ridge waveguide 8a, the first trench 10a and the adjacent second trench 10b have a predefined, constant distance A in relation to one another, which is measured in the example shown at the bottom of the two trenches 10a,b and which can be, for example, approximately 15 μm. A right side wall 11a of the first trench 10a and an adjacent left side wall 11b of the second trench 10b facing towards the first trench 10a form the side walls 11a, 11b of the first ridge waveguide 8a. This applies accordingly to the trenches 10b-d and the second and third ridge waveguides 8b, 8c.

To create the trenches 10a-d and in this way to form the ridge waveguides 8a-c, the pulsed laser beam 4 and the diamond crystal 2 are moved in relation to one another. The laser processing head 5 is arranged fixed in place in the example shown in FIG. 1. To generate a movement of the pulsed laser beam 4 and the diamond crystal 2 in relation to one another, the translation platform 7 is therefore moved along a feed direction 12, which corresponds to the Y direction of the XYZ coordinate system. The pulsed laser beam 4 is moved in this case multiple times along laterally (i.e., in the X direction) offset ablation paths 13 to generate a respective trench 10a-d, as shown by way of example in FIG. 2 for the second trench 10b. It is obvious that the movement of the diamond crystal 2 along a respective ablation path 13 can take place in the positive Y direction and the adjacent ablation path 13 can be travelled in the negative Y direction to accelerate the ablation process.

As can also be seen in FIG. 1, the diamond crystal 2 is not arranged directly on the translation platform 7, but rather on a temperature-control unit 14 in the form of a heatable susceptor which can be formed, for example, from a metallic material, from a ceramic, or from silicon. The susceptor is electrically heated via a resistance heater during the ablation of the material of the diamond crystal 2 to a temperature T, which is between 700° C. and 1000° C. in the example shown. The temperature T of the diamond crystal 2, in particular also the temperature T at the surface 2a of the diamond crystal 2, is also in the temperature range between 700° C. and 1000° C. The etching rate during the material removal is increased by the heating of the diamond crystal 2. However, the etching rate cannot be increased arbitrarily by the increase of the temperature T of the diamond crystal 2, since upon exceeding a specific threshold temperature, which is typically approximately 1000° C., the diamond material reacts very quickly with oxygen and combusts. It is therefore necessary to keep the diamond crystal 2 below a threshold temperature for the thermal oxidation. It is obvious that the diamond crystal 2 is not first heated during the radiation of the pulsed laser beam 4 to a temperature T in the above-indicated temperature range, but rather typically already before the beginning of the laser ablation method.

As indicated by an arrow in FIG. 1, a fluid F, which in the example shown forms a gas flow of an inert gas, for example, nitrogen, can be supplied to the surface 2a of the diamond crystal 2. The gas flow or the fluid F is aligned against the feed direction 12 in FIG. 1 to transport away removed or ablated material. The gas flow can be generated, for example, with the aid of a nozzle attached to the laser processing head 5.

In the example shown in FIG. 1, approximately seventy ablation paths 13 are each laterally offset in the X direction to form a respective trench 10a-d, of which two adjacent ablation paths 13 are shown in FIG. 2. The lateral offset between two adjacent ablation paths 13 is approximately 3 μm in the example shown. The pulsed laser beam 4 is focused by means of a focusing device (not shown in the figures) arranged in the laser processing head 5, for example, in the form of a focusing lens, on the diamond crystal 2, specifically in a focal plane E, which corresponds in the example shown in FIG. 2 approximately to the surface 2a of the diamond crystal 2. In the example shown in FIG. 2, the (minimum) focus diameter of the laser beam 4 is approximately 17 μm.

The parameters of the pulsed laser beam 4 are optimized for a planar removal of the material of the diamond crystal 2. However, it is obvious that it can be sufficient if the laser beam 4 is only moved along a single ablation path 13 in the feed direction 12 to form a trench 10a-d. To increase the depth of a respective trench 10a-d, the process described further above of removing material along multiple laterally offset ablation paths 13 can possibly be repeated multiple times, so that the ablation paths 13 are located vertically one over another. In this way, a respective trench 10a-d can be created having a desired width and depth.

To smooth the side wall 11b of the second trench 10b shown in FIG. 2, which forms the (right) side wall of the first ridge waveguide 8a, the diamond crystal 2 and the laser beam 4 are moved in relation to one another multiple times, for example, at least five times, along one and the same ablation path 13 in the feed direction 12. In this case, the laser parameters, for example, the pulse duration τ, the feed speed, the (average) power, etc. can differ during the first travel along the ablation path 13 from the laser parameters which are used during the second, third, . . . travel of the ablation path 13: The laser parameters during the first travel along the ablation path 13 are optimized here for the planar removal, while the laser parameters during the second, third, . . . travel of the ablation path 13 are optimized for the smoothing of the side wall 11b of the ridge waveguide 8a. Alternatively or additionally, smoothing of the side walls 11a, 11b can also take place in another way, as described in more detail further below.

As can be seen in FIG. 2, the side walls 11a,b of the ridge waveguide 8a, which was produced in the manner described further above, do not extend exactly perpendicularly to the surface 2a of the optical crystal 2, but rather are slightly inclined in relation to the vertical or to the normal direction 14 of the surface 2a of the optical crystal 2.

To create ridge waveguides 8a-c having the steepest possible side surfaces 11a,b, as shown in FIG. 1, it has proven to be advantageous, during the ablation or during the movement of the pulsed laser beam 4 and the diamond crystal 2 in relation to one another, to tilt the beam axis 6 of the laser beam 4 at an angle θ in relation to the normal direction 15 of the surface 2a of the diamond crystal 2, specifically in the example shown transversely to the feed direction 12, i.e., in the XZ plane.

To achieve this, the laser processing head 5 can have a scanner device 15, which enables a (scanning) angle θ to be set, at which the laser beam 4 exits from the laser processing head 5, as shown by way of example in FIG. 3. The scanning device 16 (trepanning system) generally has two scanner mirrors tiltable independently of one another, one scanner mirror rotatable around two axes of rotation, or a combination of a polygon scanner and a rotatable mirror scanner or scanner mirror in order to be able to set the scanning angle θ not only in the XZ plane, as shown in FIG. 3, but rather orient or align the laser beam 4 arbitrarily upon the exit from the laser processing head 5. The scanner device 16 can have a polygon scanner, for example, to deflect the laser beam 4 in the YZ plane to form the trenches 10a-d along the feed direction 12. In this case, it is advantageous if a focusing device in the form of a telecentric plane-field optical unit is arranged in the laser processing head 5 in order to focus the laser beam 4 after the deflection on the diamond crystal 2.

Due to the possibility of displacing the diamond crystal 2 with the aid of the translation platform 7 in the X direction and Y direction, for each orientation of the feed direction 12 in the XY plane, the scanning angle θ can be set independently from the location at which the laser beam 4 is incident on the surface 2a of the optical crystal 2. This is advantageous since the scanning angle θ, at which the beam axis 6 of the laser beam 4 is aligned in relation to the normal direction 14 of the surface 2a of the optical crystal 2, is generally to be aligned in a plane perpendicular to the feed direction 12, as described in more detail further below. Two scanning angles −θ, +θ are shown by way of example in FIG. 3, at which the beam axis 6 of the laser beam 4 can be aligned in the XZ plane relative to the normal direction 15.

There are also other options for aligning the laser beam 4 at an angle θ in relation to the normal direction 15 of the diamond crystal 2. For example, a platform on which the diamond crystal 2 is mounted can be tilted at an angle to the horizontal plane (XY plane) as described in detail in DE 10 2019 214 684 A1.

To create the waveguides 8a-c shown in FIG. 1 having side surfaces 11a,b rising as steeply as possible, the ablation of material described in conjunction with FIG. 1 for producing the trenches 10a-d can be carried out. In contrast to the above-described method, the beam axis 6 of the laser beam 4, during the formation of a respective trench 10a-d at least along ablation paths 13 which extend adjacent to a side wall 11a,b of a respective ridge waveguide 8a, 8b, . . . , is tilted at an angle −θ, +θ to the normal direction 14 of the surface 2a of the optical crystal 2, which is inclined away from the respective side wall 11a,b, as is also described in DE 10 2019 214 684 A1. To create the steepest possible side walls 11a,b aligned perpendicularly to the surface 2a of the optical crystal 2, it has proven to be advantageous if the angle θ is between 2° and 60°, preferably between 10° and 45°, in particular between 15° and 30°.

As can also be seen in FIG. 3, the diamond crystal 2 and the temperature-control unit 14 in the form of the susceptor are arranged in a process chamber 17 sealed off in a gas-tight manner from the environment. The illustration of the translation platform 7 was omitted in FIG. 3 for reasons of clarity. For the irradiation of the laser beam 4, the process chamber 17 has a window 18 transparent to the laser wavelength λ_{L}, which consists in the example shown of quartz glass. A residual gas atmosphere having a total pressure p in the order of magnitude of approximately 10 mbar to approximately 100 mbar prevails in the process chamber 17. The total pressure p can be set with the aid of a vacuum pump 19 or the process chamber 17 can be evacuated with the aid of the vacuum pump 19. After the evacuation, the interior of the process chamber 17 is separated with the aid of a first valve 20a from the vacuum pump 19. The total pressure p in the process chamber 17 is monitored with the aid of a pressure meter 21. If necessary, a control unit provided in the device 1 can act on the vacuum pump 19 to regulate the total pressure p in the process chamber 17 to a predefined setpoint value.

Via a second and third valve 20b, 20c, a mixture made of a reactive gas, in the example shown in the form of oxygen O₂, and an inert gas, in the example shown in the form of nitrogen N₂, is introduced into the interior of the process chamber 17. The partial pressures of oxygen O₂ and of nitrogen N₂ in the process chamber 17 are in the order of magnitude of approximately 10:1 to 100:1.

The three valves 20a-c are shutoff valves, which can also be activated with the aid of a control unit to set the partial pressure or the concentration of the inert gas N₂ and the reactive gas 02 in the interior of the process chamber 17. In principle, with the aid of the two valves 20b,c, an arbitrary mixture ratio of the inert gas N₂ and the reactive gas 02 can be set in the process chamber 17. With the aid of the reactive gas 02, the effect of the irradiated pulsed laser beam 4 can be amplified. The inert gas N₂ ensures that undesired burn-off of the diamond material does not occur.

Due to the additional temperature action on the diamond crystal 2, in the method described further above, the pulse energies of the pulsed laser beam 4 which is used for the laser ablation can be reduced. It is possible, but not absolutely necessary, to keep the temperature T of the diamond crystal 2 constant or to set a predefined time curve of the temperature T. In general, with a constant heating power of the temperature-control unit 14, for example, at a predefined current of the resistance heater, which is used for heating the susceptor, a temperature equilibrium is set in the process chamber 17, so that regulation or monitoring of the temperature T can be omitted.

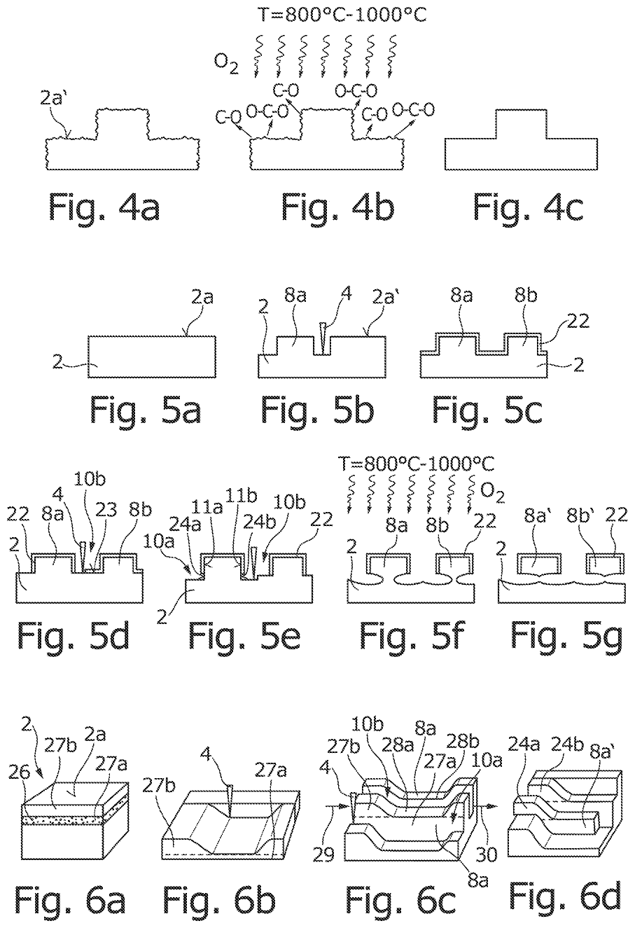

The arrangement of the diamond crystal 2 in the process chamber 17 enables smoothing of the structured surface 2a′ to be carried out after the material removal, as is described hereinafter on the basis of FIGS. 4a-c. For the smoothing, a controlled thermal oxidation of the structured surface 2a′ is carried out at a temperature between 600° C. and 1100° C., for example, between 650° C. and 1000° C., typically between 800° C. and 1000° C., in an oxygen O₂-containing atmosphere in the interior of the process chamber 17. In this case, the carbon of the diamond crystal 2 is oxidized, as indicated in FIG. 4b. The thermal oxidation is carried out over a comparatively short duration, which is generally between a few seconds and one minute. The process parameters, in particular the temperature T, the pressure p, the partial pressure of oxygen O₂, and the duration of the thermal oxidation in the process chamber 17 are deliberately set here to minimize roughness without a (significant) material removal occurring.

It is described hereinafter on the basis of FIGS. 5a-f how freestanding microstructures 8a′-8c′ are formed from the microstructures 8a-c shown in FIG. 1.

FIG. 5a shows the diamond crystal 2 having a planar surface 2a, onto which the pulsed laser beam 4 is radiated, to remove material from the diamond crystal 2, as indicated in FIG. 5b, in order to create the ridge waveguides 8a-c in the way described in conjunction with FIG. 1.

FIG. 5c shows a masking layer 22 deposited on the structured surface 2a′, which is used to protect the structured surface 2a′ from a subsequent etching attack. As can be seen in FIG. 5c, the masking layer 22 is deposited homogeneously on the structured surface 2a′ and has an essentially constant thickness, which is in the order of magnitude between approximately 10 nm and approximately 1000 nm, ideally between 200 nm and 300 nm. To enable such a conformal deposition of the masking layer 22 which is as homogeneous as possible on the structured surface, the deposition of the masking layer 22 is typically carried out by a CVD process or by an ALD process. The material of the masking layer 22 is a temperature-stable nitride or oxide, for example, SiO₂, Al₂O₃, SiN, or another amorphous, temperature-stable oxide or nitride such as TiO or TiO₂, ZrO, TiN, AlN, or the like. The deposition of the masking layer 22 typically does not take place in the process chamber shown in FIG. 3, but rather in a coating facility especially provided for depositing layers, for example, in a so-called CVD reactor.

As shown by way of example in FIG. 5d for the second trench 10b, the masking layer 22 is removed at the bottom 23 of the respective trenches 10a-d. In the example shown in FIG. 5d, the masking layer 22 is removed or ablated over the entire width of the bottom 23 which extends between the two ridge waveguides 8a,b. It is possible in principle that the masking layer 22 is only removed in the region of the side walls 11a,b and not over the entire width of the bottom 23 of a respective trench 10a-b.

In the longitudinal direction of the trenches 10a-d (i.e., in the Y direction), the masking layer 22 is only removed in a section in which the freestanding ridge waveguides 8a′-8c′ shown in FIG. 3 are to be formed. In a region in the longitudinal direction in front of and behind the region in which the freestanding ridge waveguides 8a′-8c′ are to be formed (indicated by dashed lines in FIG. 3), the masking layer 22 is not removed at the bottom 23 of the respective trenches 10a-d.

For the local removal of the masking layer 22, in the example shown, the pulsed laser beam 4 described in conjunction with FIG. 1 to FIG. 3 is used. For this purpose, however, a laser beam can also be used which has a different wavelength. The pulse duration used for the removal of the masking layer 22 can also deviate from the pulse durations described further above in conjunction with the material removal. The partial removal of the masking layer 22 can also be carried out by a so-called lift-off process, in which a photoresist is lithographically structured so that it only remains in the region of the bottom 23 of the respective trenches 10a-d or in a section in which the ridge waveguides 8a′-8c′ are to be formed. After deposition of the masking layer 22 over the entire surface, the remaining photoresist is removed, for example, by a solvent attack, by which the masking layer 22 present on the remaining photoresist is also dissolved simultaneously.

As can be seen in FIG. 5e, after the removal of the masking layer 22 from the bottom of a respective trench 10a-d, the trench 10a-d is deepened by additional removal of material of the diamond crystal 2. The deepening of a respective trench 10a-d is carried out at least along the two side walls 11a,b of a respective waveguide 8a, in order to form a section 24a,b extending the side walls 11a,b, which is not covered by the masking layer 22.

To form the freestanding waveguide structures 8a′-8c′, the waveguide structures 8a-c shown in FIG. 5e are undercut in an isotropic etching process, as indicated in FIG. 5f The fact is utilized here that the sections 24a,b of the side walls 11a,b not covered by the masking layer 22 are not protected from an etching attack, so that the material of the diamond crystal 2 below the waveguide 8a-c can be completely removed and the freestanding waveguide 8a′-8c′ is formed, as shown in FIG. 5g.

The undercutting of the waveguide structures 8a-c is carried out by thermal oxidation of the diamond crystal 2 at a temperature T between 600° C. and 1100° C., typically between 800° C. and 1000° C., in an oxygen O₂-containing atmosphere, which prevails in the example shown in the process chamber 17, into which the diamond crystal 2 provided with the masking layer 22 is introduced. The thermal oxidation is an isotropic etching process in which only the regions of the surface of the diamond crystal 2 not covered by the masking layer 22 are attacked. The process duration of the thermal oxidation depends on the etching speed which prevails with the respectively set process parameters (temperature T, pressure p, content or partial pressure of the oxygen O₂ in the environment, etc.) in the process chamber 17 and can be from a few seconds to several minutes.

It can be advantageous to generate an oxygen plasma for the undercutting, as is the case, for example, in a CVD reactor. The reactivity of the oxygen O₂ is increased by the oxygen plasma and the temperature T required for the thermal oxidation can be reduced. The oxygen plasma can be generated with the aid of a plasma generating device in the process chamber 17 shown in FIG. 3, however, it is also possible that the diamond crystal 2 is transferred into a device especially provided for this purpose, for example, into a plasma etching facility. After the exposure of the waveguide structures 8a′-8c′, the masking layer 22 is typically completely removed from the structured surface 2a′.

The freestanding waveguide structures 8a′-8c′ are attached to the remaining diamond crystal 2 via further (first and second) waveguide structures 24a-c, 25a-c, which adjoin the freestanding waveguide structures 8a′-8c′ in the longitudinal direction of the trenches 10a-c, as shown in FIG. 3. The further first waveguide structures 24a-c adjoin the freestanding waveguide structures 8a′-8c′ on a first side, in front in FIG. 3, while the further second waveguide structures 25a-c adjoin the freestanding waveguide structures 8a′-8c′ on a second side on the rear in FIG. 3. The further first waveguide structures 24a-c are used to supply light to the freestanding waveguide structures 8a′-8c′ and the further second waveguide structures 25a-c are used to discharge light from the freestanding waveguide structures 8a′-8c′. The freestanding waveguide structures 8a′-8c′ also allow a confinement of the modes guided therein in the vertical direction. In particular, by way of a variation of the depth of the trenches in the structuring of the surface 2a of the diamond crystal 2, a variation of the height of the respective freestanding waveguide 8a′-8c′ can also be carried out.

For the case in which the diamond crystal 2 is doped in the region of the freestanding waveguide structures 8a′-8c′ with colour centres, for example, with NV centres, the freestanding waveguide structures 8a′-8c′ can be used as spatially precise defined measuring regions, for example, for magnetic field measurement. In this case, it is advantageous if the further waveguide structures 24a-c, 25a-c, which adjoin the freestanding waveguide structures 8a′-8c′, are not doped with NV centres. In order to create a diamond crystal 2 structured in this way, a procedure can be used in a way which is described hereinafter in conjunction with FIGS. 6a-d.

The diamond crystal 2 to be structured has in this case two adjoining layers 27a, 27b, of which the first layer 27a is spaced apart from the surface 2a to be structured and of which the second layer 27b directly adjoins the surface 2a to be structured (cf. FIG. 6a). The first layer 27a is a buried layer, in which the diamond crystal 2 is doped with NV centres, while the diamond crystal 2 is not doped with NV centres in the second layer 27b and also below the first layer 27a. The concentration of the NV centres in the first layer 27a is typically between approximately 0.1 ppm and 2 ppm, for example between 0.3 ppm and 0.7 ppm, in particular approximately 0.5 ppm.

For the formation of the freestanding waveguides 8a′-8c′ in the first layer 27a, initially the surface 2a of the diamond crystal 2 is structured by means of laser ablation, as was described further above in conjunction with FIG. 1. During the laser ablation, in a first step shown in FIG. 6b, the second layer 27b is removed in a partial region which is above the respective waveguide structures 8a-c to be formed. As shown in FIG. 6b, material of the second layer 27b is also removed in this case, which is located between the waveguide structures 8a-c to be formed. In two transition regions adjoining the completely removed partial region, at which later the further waveguide structures 24a-c, 25a-c adjoin the freestanding waveguide structures 8a′-8c′, the second layer 27b is partially removed.

In a subsequent step, the diamond crystal 2 is structured as described further above in conjunction with FIG. 1 in that trenches 10a,b are formed in the diamond crystal 2 in order to form the waveguide structures 8a-c and in order to form the further waveguide structures 24a-c, 25a-c. The trenches 10a,b extend in the region of the waveguide structures 8a-c as far as into the first layer 27a and are bounded in the region of the further waveguide structures 24a-c, 25a-c on the second layer 27b. The interface between the first layer 27a and the second layer 27b is indicated by dashed lines in FIGS. 6b-d.

After the steps (not shown in the figures) of applying the masking layer 22, partially removing the masking layer 22, and deepening the trenches 10a,b to expose the respective sections of the side walls 10a,b which are not covered by the masking layer 22, which are carried out in the way described in conjunction with FIGS. 5c-e, undercutting of the waveguide structures 8a-c is carried out in the way described in conjunction with FIG. 5g, to form the freestanding waveguide structures 8a′-8c′, of which a waveguide structure 8a′ is shown by way of example in FIG. 6d.

As indicated in FIG. 6c, via the further first waveguide structures 24a-c, which are formed in the non-doped second layer 27b, excitation light 29 can be supplied to the freestanding waveguide structures 8a′-8′c, which interacts with the NV centres 26 in the first layer 27a. The fluorescent light 30 formed in this case can be collected with the aid of the further second waveguide structures 25a-c and discharged from the freestanding waveguide structures 8a′-8c′ and supplied, for example, to a detector or the like. The coupling and decoupling can take place at the end faces or at the edges of the further waveguide structures 24a-c, 25a-c with the aid of suitable coupling devices or decoupling devices, which can be the end facets of the further waveguide structures 24a-c, 25a-c, grating couplers, etc.

It is obvious that the freestanding waveguide structures 8a′-8c′ do not necessarily have to have a rectangular cross section which is constant in the longitudinal direction of the freestanding waveguide structures 8a′-8c′. For many applications, it can be advantageous if the cross section of a respective freestanding waveguide 8a′-8c′ varies in the longitudinal direction. For example, it can be favourable in the application described further above for magnetic field measurement, for optimizing the excitation density of the excitation light 29, to suitably adapt the geometry of the respective freestanding waveguides 8a′-8c′. For example, the cross section of the freestanding waveguide structure 8a′-8c′ can decrease in the propagation direction of the excitation light 29 to keep the excitation density as constant as possible in the longitudinal direction. The reduction of the cross section can be achieved by a tapering, truncated-cone-like or wedge-shaped geometry of the respective freestanding waveguide structure 8a′-8c′.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for forming at least one freestanding microstructure on a diamond crystal, the method comprising:
removing material from the diamond crystal so as to form a structured surface, wherein the removing of the material includes creating at least two trenches, each trench having a bottom and two side walls and wherein adjacent side walls of the at least two trenches form side walls of the structured surface,
depositing at least one masking layer on the structured surface,
removing at least a portion of the at least one masking layer from the bottom of each of the at least two trenches,
removing additional material from the diamond crystal at least along the side walls so as to deepen the trenches, and
undercutting the diamond crystal so as to form the freestanding microstructure.

2. The method according to claim 1, wherein the undercutting, is carried out by thermal oxidation of the diamond crystal at a temperature between 600° C. and 1100° C.

3. The method according to claim 1, further comprising performing thermal oxidation of the structured surface at a temperature between 600° C. and 1100° C. so as to smooth the structured surface.

4. The method according to claim 1, wherein the depositing of the at least one masking layer is carried out by at least one of chemical vapour deposition or atomic layer deposition.

5. The method according to claim 1, wherein the removing of the material, the removing of at least a portion of the masking layer, and/or the removing of the additional material is carried out by laser ablation using a pulsed laser beam.

6. The method according to claim 5, wherein a temperature of the diamond crystal during the removing of the material, during the at least partial removal of the masking layer, and/or during the removing of the additional material is greater than 600° C. and less than 1000° C.

7. The method according to claim 5, wherein the removing of the material includes:
radiating the pulsed laser beam onto the surface of the diamond crystal,
moving the pulsed laser beam and the diamond crystal relative to one another along a feed direction along at least one ablation path.

8. The method according to claim 5, in which the pulsed laser beam has a wavelength of less than 450 nm.

9. The method according to claim 1, further comprising disposing the diamond crystal in a gas-tight process chamber during the undercutting, during the removal of material, during the removing of the additional material, and/or during the smoothing of the structured surface.

10. The method according to claim 1, further comprising doping the diamond crystal with colour centres.

11. The method according to claim 1, further comprising:
forming at least one further microstructure in the diamond crystal, the further microstructure usable to supply excitation light to the freestanding waveguide structure and/or to discharge fluorescent light from the freestanding waveguide structure.

12. The method according to claim 11, wherein the diamond crystal comprises a first layer doped with colour centres and a second layer adjoining the first layer, wherein the second layer is not doped with the colour centres and wherein the freestanding microstructure is formed in the first layer, and wherein the at least one further microstructure is formed in the second layer.

13. The method according to claim 12, wherein the removing of the material includes removing the material from the second layer so as to expose an upper side of the microstructure to be formed.

14. A diamond crystal, comprising:
at least one freestanding microstructure produced according to the method according to claim 1.
